(19) United States
(12) Patent Application Publication
(10) Pub. No.: US 2014/0217457 A1
(43) Pub. Date: Aug. 7, 2014

(54) LIGHT-EMITTING ELEMENT CHIP AND MANUFACTURING METHOD THEREFOR

(71) Applicants: Meoung Whan Cho, Yongin (KR); Seog Woo Lee, Yongin (KR); Pil Guk Jang, Yongin (KR); Ryuichi Toba, Tokyo (JP); Yoshitaka Kadowaki, Akita (JP)

(72) Inventors: Meoung Whan Cho, Yongin (KR); Seog Woo Lee, Yongin (KR); Pil Guk Jang, Yongin (KR); Ryuichi Toba, Tokyo (JP); Yoshitaka Kadowaki, Akita (JP)

(73) Assignees: WAVESQUARE INC., Yongin-City, Gyeonggi-Do (KR); DOWA ELECTRONICS MATERIALS CO., LTD., Tokyo (JP)

(21) Appl. No.: 14/117,301

(22) PCT Filed: May 25, 2011
(86) PCT No.: PCT/JP2011/002911

§ 371 Date: Nov. 12, 2013

(51) Int. Cl. H01L 33/36; H01L 33/22

(52) U.S. Cl. CPC H01L 33/36; H01L 33/22
USPC 257/99; 438/22

(57) ABSTRACT

There is provided a light-emitting element chip which can be safely assembled and a manufacturing method therefor. A light-emitting element chip 10 has a semiconductor layer 12 including a luminescent layer 12a on a supporting portion 11. The supporting portion 11 has a concave shape, providing a support substrate in this light-emitting element chip 10, and being connected to one electrode on the semiconductor layer 12. The outer peripheral portion of the supporting portion 11 (a supporting portion outer peripheral portion 11a) surrounds the semiconductor layer 12, and is protruded to be set at a level higher than the other face 12d and the n-side electrode 15 of the semiconductor layer 12.

### TECHNICAL FIELD

The present invention relates to a light-emitting element chip and a manufacturing method therefor, and particularly relates to a light-emitting element chip using a group III nitride semiconductor and a manufacturing method therefor.

### BACKGROUND ART

The group III nitride semiconductor, which provides a material for a light-emitting element (LED), can generally be obtained by heteroepitaxially growing it on a substrate (substrate for growth) made of another material. Therefore, the structure of the light-emitting element chip using such material and the manufacturing method therefor are subjected to a restriction. On the other hand, the development of the epitaxial layer lift-off technologies, such as the laser lift-off technology and the chemical lift-off technology, has allowed the substrate to be removed after the growth. Thereby, for the group III nitride semiconductor, the study about the manufacture of a light-emitting element (LED) chip having a vertical structure, which provides electrodes vertically sandwiching the luminescent layer, has been started.

Generally, the group III nitride semiconductor light-emitting element is manufactured by vapor-phase epitaxially growing it on the substrate for growth, such as a sapphire substrate, or the like. In this case, the light-emitting structure portion produced by the vapor-phase epitaxial growth method is thin, and therefore, in the state in which the substrate for growth has been peeled off, it is difficult to handle the light-emitting structure portion as an independent one. Thereby, the light-emitting element chip having the above-mentioned vertical structure requires to be supported by a substrate, or the like, which is different from the substrate for growth, and can replace it.

Patent Document 1 discloses a method which forms a metallic sheet on the p-type nitride semiconductor layer by the plating method, which is followed by dissolving the Si as the substrate for growth. In this case, this metallic sheet serves as a support substrate for the thin semiconductor layer in place of the substrate for growth.

Patent Document 1: Japanese Unexamined Patent Application Publication No. 2004-47704

### SUMMARY OF INVENTION

### Problems to be Solved by the Invention

The light-emitting element chip (LED chip) having a vertical structure is generally handled by vacuum-chucking it with the use of a pick-up member (a collet, or the like). Thereby, it is mounted to an LED chip loading member, such as a submount, a lead frame, TO-18, or TO-39, using a conductive adhesive, such as silver paste. Thereafter, the lower electrode of the LED chip and the LED chip loading member are electrically connected to each other, and then electrical connection (wire bonding) between the upper electrode of the LED chip and the LED chip loading member is performed with an Au wire, or the like. Thereby, the LED chip is brought into the state in which it can actually be used as a light-emitting element. These operations are collectively referred to as assembly.

In the case where the uniformity of the emitted light intensity in the light-emitting face can be a problem, as with a large-sized LED chip, the electrode having such a configuration as that which makes the current uniform in the chip is used. As the upper electrode having such a configuration, that with which the bonding pad and the auxiliary electrode formed in the shape of a lattice, an annulus, or a radiation are integrated with each other is often used. On the other hand, the auxiliary electrode is not transparent to the light emitted by an LED, and therefore the portion where this auxiliary electrode is formed obstructs the light, thereby producing a dark portion. Therefore, it is preferable that the auxiliary electrode be thin. In the above-mentioned assembling operation, a flaw or a dent was caused to such a thin auxiliary electrode in some case, leading to a conduction failure.

In addition, it is publicly known that the light taking-out efficiency can be enhanced by providing irregularities on the light-emitting face (the outermost semiconductor surface). And, in the case where such irregularities were provided, the upper electrode (including the auxiliary electrode) was generally formed on the flat face, and only on the irregular surface, a protection film was formed. Even in such case, in the above-mentioned assembling operation, a chip or a crack tended to be produced on the irregular surface and particularly the end portion.

The inventors have proposed an ohmic electrode which is particularly effective if formed on such an irregular surface (International Application No. PCT/JP2010/007611). However, with this ohmic electrode on the irregular surface, particularly such a chip or a dent tended to be produced as compared to the ohmic electrode formed on the ordinary flat face.

In other words, there has been a demand for a light-emitting element chip which has a structure allowing the light-emitting face having an electrode and a light taking-out portion to be protected in the assembly.

The present invention has been made in view of the above-mentioned problem, and it is an object of the present invention to provide a light-emitting element chip which can be assembled safely, and a manufacturing method therefor.

### Means for Solving the Problems

In order to accomplish the above-mentioned purpose, the light-emitting element chip and the manufacturing method therefor in accordance with the present invention is configured as follows:

In other words, the light-emitting element chip is a light-emitting element chip, including a configuration in which a semiconductor layer having a luminescent layer is formed on a conductive supporting portion, the supporting portion being connected to one electrode connected to one face of the semiconductor layer, irregularities being formed on the other face of the semiconductor layer, and the other electrode being formed on the other face, the supporting portion having an outer peripheral portion surrounding the periphery of the other face of the semiconductor layer, with the outer peripheral portion being protruded to above the other face of the semiconductor layer and the other electrode.

The protruded portion formed of a part of this supporting portion is capable of physically protecting the other face of the semiconductor layer and the other electrode.

It is preferable that the protruded top portion of the outer peripheral portion be located higher than the surface of the other electrode by 0.2 μm or over, and further the side face of the semiconductor layer be tapered, being adjacent to the outer peripheral portion of the supporting portion with at least an insulator layer being sandwiched therebetween.

In addition, it is preferable that the supporting portion be integrally formed by a dry or wet deposition method, being made of a metal or an alloy.

In addition, it is preferable that the semiconductor layer be formed of a group III nitride semiconductor, micro surfaces constituting the irregularities on the other face providing a semi-polar plane composed of a group of {10-1-1} planes.

The light-emitting element chip manufacturing method is a light-emitting element chip manufacturing method for manufacturing a plurality of light-emitting element chips using a single growth substrate, including: the epitaxial growth step of sequentially forming a lift-off layer and a semiconductor layer having a luminescent layer on the lift-off layer on the growth substrate; the separation groove forming step of forming, between places corresponding to adjacent light-emitting element chips, a separation groove in which the growth substrate is exposed by removing the semiconductor layer and the lift-off layer; the insulator layer forming step of forming, in the separation groove, an insulator layer which at least surrounds the side face of the semiconductor layer that faces the separation groove; the first electrode forming step of forming one electrode on one face of the semiconductor layer that is the surface thereof on the side opposite to the growth substrate; the supporting portion forming step of forming a supporting portion for supporting the semiconductor layer on the face of the semiconductor layer on the side opposite to the growth substrate, and in the separation groove; the lift-off step of separating the semiconductor layer and the growth substrate from each other by removing the lift-off layer by a wet treatment; the semiconductor layer etching step of etching away the other face of the semiconductor layer that has been exposed by the lift-off step, thereby the supporting portion surrounding the periphery of the other face (the outer peripheral portion of the supporting portion that has been formed in the separation groove) being protruded to above the other face; the irregularities forming step of performing a treatment for forming irregularities on the other face; and the second electrode forming step of forming the other electrode on the other face.

It is preferable that, in the separation groove forming step of the light-emitting element chip manufacturing method, the side face of the semiconductor adjacent to the separation groove be tapered.

In addition, it is preferable that, in the irregularities forming step of the light-emitting element chip manufacturing method, the other face be etched away using an alkaline solution.

Further, it is preferable that, in the supporting portion forming step, the supporting portion be formed such that there exists a thru-hole in the supporting portion; and in the lift-off step, an etchant for etching away the lift-off layer be supplied to the lift-off layer through the thru-hole.

### Advantages of the Invention

In accordance with the present invention, a light-emitting element chip which can be assembled safely and a manufacturing method therefor can be provided.

### BRIEF DESCRIPTION OF THE DRAWINGS

FIG. 1 gives a top view (a) and a sectional view (b) along a line of A-A of a light-emitting element chip according to the present embodiment of the present invention;

FIG. 2 gives sectional views (left), and top views (right) therefor for the steps (group 1) of the manufacturing method for a light-emitting element chip according to an embodiment of the present invention;

FIG. 3 gives sectional views (left), and top views (right) therefor for the steps (group 2) of the manufacturing method for the light-emitting element chip according to the embodiment of the present invention;

FIG. 4 gives sectional views (left), and top views (right) therefor for the steps (group 3) of the manufacturing method for the light-emitting element chip according to the embodiment of the present invention;

FIG. 5 gives sectional views (left), and top views (right) therefor for the steps (group 4) of the manufacturing method for the light-emitting element chip according to the embodiment of the present invention;

FIG. 6 is an SEM photograph showing the section in the vicinity of the periphery of the light-emitting element chip providing Example of the present invention when viewed from diagonally above;

FIG. 7 gives sectional views (left), and top views (right) therefor for the steps (group 1) of the manufacturing method for a light-emitting element chip providing Comparative Example;

FIG. 8 gives sectional views (left), and top views (right) therefor for the steps (group 2) of the manufacturing method for the light-emitting element chip providing Comparative Example;

FIG. 9 is a sectional view of the light-emitting element chip providing Comparative Example;

FIG. 10 is a histogram of the emission intensity of the light-emitting elements of Example and Comparative Example; and

FIG. 11 gives the result of determination of the relationship between the emission intensity and the taper angle θ; and

FIG. 12 gives photographs of the top view after the phosphor layer having been formed in Example, and Comparative Example.

### BEST MODE FOR CARRYING OUT THE INVENTION

Hereinbelow, a light-emitting element chip and a manufacturing method therefor which provide a preferred embodiment of the present invention will be explained with reference to the drawings. In the present invention, the light-emitting element chip means a chip in the state before being assembled, and will be expressed as such for discrimination from the light-emitting element which is produced by assembling it.

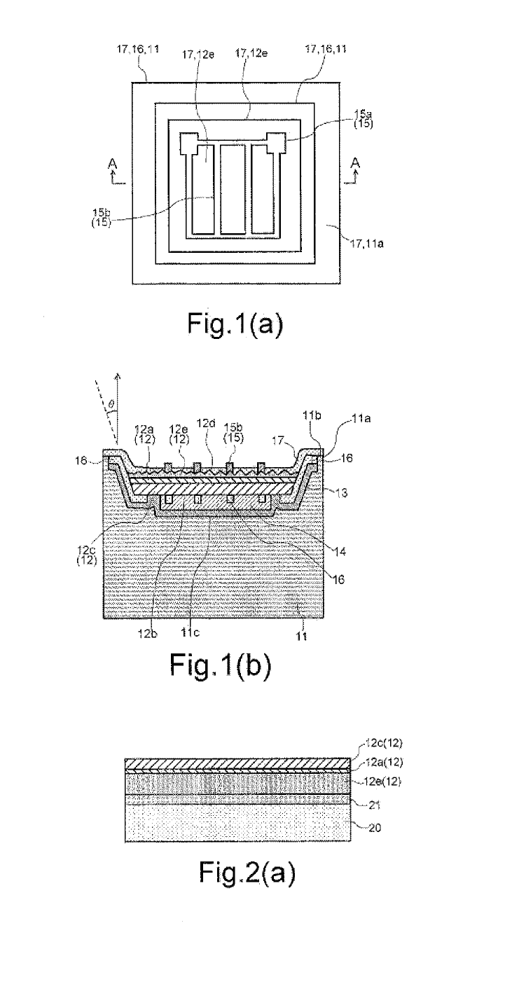

FIG. 1 gives a top view (a) and a sectional view (b) of the light-emitting element chip according to the present embodiment of the present invention. A light-emitting element chip 10 has a semiconductor layer 12 including a luminescent layer 12a on a supporting portion 11. The supporting portion 11 has a concave shape, providing a support substrate in this light-emitting element chip 10, and being connected to one electrode on the semiconductor layer 12. The light-emitting element chip 10 emits light towards the upper side in FIG. 1(b).

One face 12b (the lower face in FIG. 1(b)) of the semiconductor layer 12 is connected to a bottom portion 11c of the supporting portion 11 through a base layer 13. The one face 12b of the semiconductor layer 12 is composed of a p-type semiconductor layer 12c, and there is formed a p-side electrode 14 which is ohmic-bonded to the p-type semiconductor layer 12c.

In the other face 12d (the upper face in FIG. 1(b)) of the semiconductor layer 12, an irregular structure is formed, and there is partially formed an n-side electrode 15. The other face 12d of the semiconductor layer 12 is composed of an n-type semiconductor layer 12e, and the n-side electrode 15 is formed of a metal which is ohmic-bonded to the n-type semiconductor layer 12e. As shown in FIG. 1(a), the n-side electrode 15 has a bonding pad part 15a to which a bonding wire is connected, and an auxiliary electrode 15b for supplying the current uniformly in the chip. The light emitted by this light-emitting element chip 10 toward the upper side is obstructed by the n-side electrode 15. The bonding pad part 15a must have a minimum area for performing bonding thereon, however, it is preferable that the auxiliary electrode 15b have a small width. On the other hand, if this width is smaller, the resistance of the auxiliary electrode 15b is increased, and therefore, the width and the height of the auxiliary electrode 15b are determined as appropriate in consideration of the wiring resistance.

In addition, on the one face of the semiconductor layer 12, an insulator layer 16 is patterned such that it is symmetrical with the auxiliary electrode 15b in the vertical direction, the semiconductor layer 12 being sandwiched therebetween. With the above-mentioned structure, the current flows in the vertical direction in FIG. 1(b) in the semiconductor layer 12 across the p-side electrode 14 and the n-side electrode 15. Here, by providing the insulator layer 16 so as to be symmetrical with the n-side electrode 15 in the vertical direction, the flow of current toward just under the n-side electrode 15 is restricted, thereby the light emission from the semiconductor layer 12 just under the n-side electrode 15 is restricted, and with this restriction, the emitted-light intensity in the place which is not just under the n-side electrode 15 can be enhanced, the restriction also contributing to the improvement in in-face uniformity of light emission.

In addition, the outer peripheral portion of the supporting portion 11 (the supporting portion outer peripheral portion 11a) surrounds the semiconductor layer 12, being protruded from the other face 12d and the n-side electrode 15 of the semiconductor layer 12, thereby being set at a higher level (on the upper side in FIG. 1(b)). The insulator layer 16 is formed so as to cover the peripheral end portion of the semiconductor layer 12, thereby the supporting portion 11 and the n-type semiconductor layer 12e being electrically insulated from each other.

The top portion 11b of the supporting portion outer peripheral portion 11a of the supporting portion 11 is at a level higher than the surface of the n-side electrode 15 by, for example, 0.2 μm. In addition, the place other than the n-side electrode 15 in the surface of the semiconductor layer 12 is covered with a protection film 17.

The semiconductor layer 12 provides a luminescent layer 12a between an n-type GaN based nitride layer (n-type semiconductor layer: n-type layer) 12e and a p-type GaN based nitride layer (p-type semiconductor layer: p-type layer) 12c. The luminescent layer 12a is a layer having a high luminous efficiency, such as a multiple quantum well layer (MQW) composed of, for example, a GaN based nitride layer. The configuration of this semiconductor layer 12 is the same as that which is used with an ordinary LED.

The insulator layer 16 and the protection film 17 are both formed of SiO₂, or the like. The supporting portion 11 is made of a material (for example, copper (Cu) or nickel (Ni)) formed by the bonding method or the wet deposition method (such as plating), or the like. The base layer 13 is made of a metal which provides a seed layer for plating, such as nickel (Ni), gold (Au), platinum (Pt), or Cu (for Cu plating), or Ni, paradium (Pd), Au, or Pt (for Ni plating). However, the base layer 13 may be produced as a laminated structure containing these materials as appropriate.

As the material for the p-side electrode 14, a material which can be ohmically connected to the p-type layer 12c, a simple substance metal of, for example, Ag, Rh, Ru, or the like, or an alloy or a laminated structure containing these can be used. Or, an Au—Ni alloy, a simple substance of Pt or Pd, and an alloy of these can also be used. However, the p-side electrode 14 also functions as a light reflection layer, and from this viewpoint, Ag and its alloy family, which have a reflectivity to visible light as high as 85% or over, or Rh and Ru, which have a high reflectivity in the ultraviolet region, are particularly preferably used in accordance with the application. In this case, by using such a material as the material on the side where the p-side electrode 14 is to be contacted with the semiconductor layer 12 (p-type layer 12c), the reflectivity can be increased or the contact resistance can be reduced.

As shown in FIG. 1(a), the semiconductor layer 12 has a rectangular planar shape, and provides a geometry which would be produced as if this semiconductor layer 12 is fitted into the concave portion of the supporting portion 11 to be accommodated therein.

In the other face 12d of the semiconductor layer 12, there is formed an irregular structure. The macro surface of the other face 12d (the surface which would be provided if the irregularities are averaged or flattened) is, for example, a (000-1) N polar plane. On the other hand, the micro surface constituting the irregular surface provides a semi-polar plane composed of a group of {10-1.1} planes. In other words, this irregularities are constituted by a semi-polar plane composed of a group of {10-1-1} planes having a minute area. The detail of this point will be explained with the manufacturing method later-described.

As described above, with the light-emitting element chip 10, the supporting portion outer peripheral portion 11a of the supporting portion 11 is protruded to above the other face 12d of the semiconductor layer 12, which has an irregular structure, and the surface of the other electrode 15. Thereby, the n-side electrode 15 (particularly the auxiliary electrode 15b) will not be directly contacted with a collet or the surface of the working bench, and the like, at the time of assembly, thereby the possibility that a flaw or dent may be produced being practically eliminated, whereby occurrence of a conduction failure can be suppressed. Further, occurrence of a chip and initiation of a crack on the irregular surface 12d or in the light-emitting portion of the semiconductor layer 12 can be suppressed. Also, from the viewpoint of protection of the light taking-out face and the light-emitting portion, the assembly can be performed with safety. Herein, as later described, the supporting portion 11 and the supporting portion outer peripheral portion 11a can be integrally formed. The portion which is protruded to above the other face 12d of the semiconductor layer 12 and the n-side electrode (the other electrode) 15 can be formed by bonding a member to the supporting portion 11, however, the manufacturing process will become complicated, and there will be presented a problem with the strength, thereby the bonding scheme is not preferable. By forming the supporting portion 11 and the supporting portion outer peripheral portion 11a integrally, the manufacturing process is simplified with the mechanical strength of the formed portion being able to be increased.

Further, in the case where a conventional flat supporting portion is used, the light which is emitted from the luminescent layer toward the lateral direction was caused to leak in the lateral direction, thereby the light could not be taken out with a sufficient effectiveness. Contrarily to this, with this light-emitting element chip 10, the light which has reached the side face from the luminescent layer 12a is reflected by the supporting portion outer peripheral portion 11a, whereby the light can be taken out with a sufficient effectiveness. In that case, it is preferable that the angle of the tapered portion inside the concave portion of the supporting portion 11 that is contacted with the semiconductor layer 12 through the insulator layer 16 be inclined in the range of from 10° to 80°. How to set this angle will be described later. The taper angle θ in this case is defined as illustrated in FIG. 1(b).

Next, the manufacturing method for the light-emitting element chip 10 according to the present embodiment of the present invention will be explained. The semiconductor layer 12 used for this light-emitting element chip 10 can be obtained by epitaxially growing it on a growth substrate. However, with the light-emitting element chip 10 which is actually manufactured, this growth substrate is removed, and the supporting portion 11, which is different from the growth substrate, is connected on the side opposite to the side where there was the growth substrate. In addition, a number of structures in FIG. 1 are formed using a single large wafer (the growth substrate), and finally individual light-emitting element chips 10 are obtained by separation.

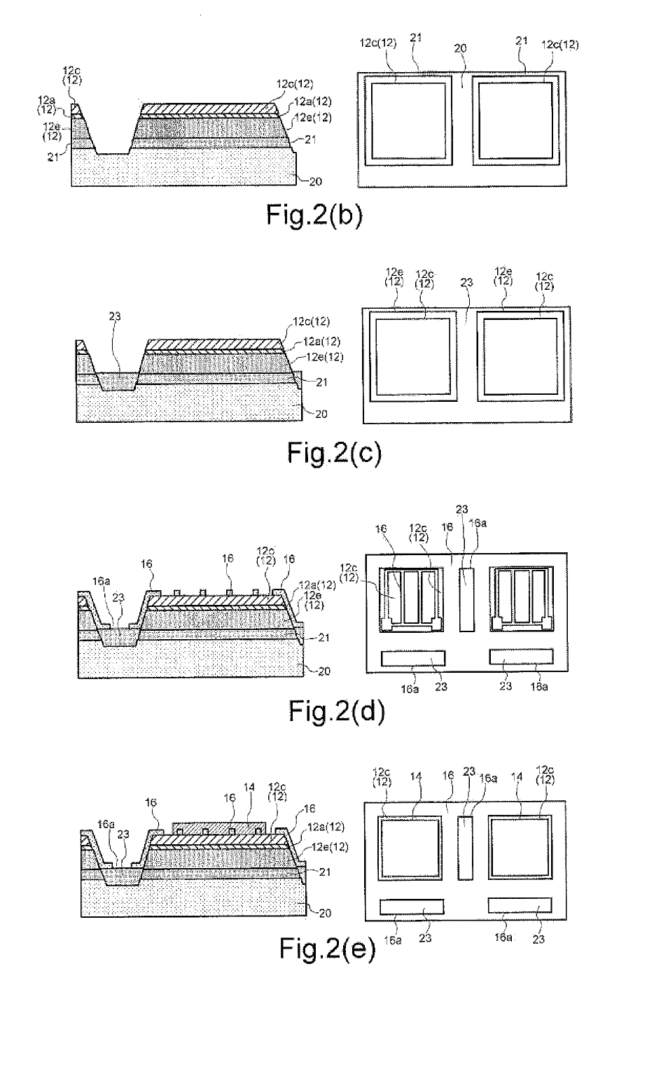

FIGS. 2 to 5 gives sectional views (at left), and top views therefor (at right) of the forms at the steps of manufacturing the above-mentioned light-emitting element chip 10. Herein, the sectional views indicate the places which each corresponds to a particular place in FIG. 1(b). In addition, the top views indicate a region including two light-emitting element chips 10 which are adjacent to each other.

First, as shown in FIG. 2(a), on a growth substrate 20, a lift-off layer 21, an n-type GaN layer (n-type semiconductor layer: n-type layer) 12e, a luminescent layer 12a, a p-type GaN layer (p-type semiconductor layer: p-type layer) 12c are sequentially deposited (the epitaxial growth step). As the growth substrate 20, a sapphire substrate or an AlN template substrate (a substrate having an AlN layer on the surface of the sapphire) are particularly preferably used. The deposition of the n-type layer 12e, the luminescent layer 12a, and the p-type layer 12c is performed by, for example, the metal organic chemical vapor deposition method (MOCVD method), with the n-type layer 12e being doped with an impurity providing the donner, while the p-type layer 12c being doped with an impurity providing the acceptor. The material of these layers is not limited to GaN, and may be a material having a composition containing aluminum (Al), indium (In), boron (B), or the like, which is of group III.

In addition, as the material for the lift-off layer 21, such a metal as chromium (Cr) can be used. Deposition of the lift-off layer 21 can be performed by the sputtering method, the vacuum vapor deposition method, or the like. Before growing the n-type layer 12e after forming the lift-off layer 21, by making a nitriding treatment, such as a heating treatment in the ammonia atmosphere, the lift-off layer 21 can be nitrided to provide, for example, a chromium nitride layer (metal nitride layer: CrN layer). This treatment allows the semiconductor layer 12 having a better characteristic to be obtained, and the later-described lift-off step to be performed easier.

Next, as shown in FIG. 2(b), on the growth substrate 20, a separation groove for separating the semiconductor layers 12 corresponding to the individual light-emitting element chips 10 is formed (the separation groove forming step). This step is performed by forming a mask on the semiconductor layer 12 (p-type layer 12c) and then making dry etching for removing the semiconductor layer 12 and the lift-off layer 21 in the region other than the region which is covered by the mask (i.e., the element region). In other words, by the separation groove formed by this dry etching, a plurality of regions having a rectangular shape when viewed from top at right in FIG. 2(b) are formed.

In this step, by adjusting the dry etching conditions, such as the type of gas, the pressure thereof, and the etching speed, the anisotropy of the dry etching can be adjusted. By this, the taper angle θ in the end portion of the semiconductor layer 12 can be adjusted. It is preferable that this taper angle θ be between 10° to 80°. Such taper angle adjustment is difficult to be performed in the wet etching, and the wet etching tends to cause the orientation of the slope to be reverse to that in FIG. 2(b), i.e., to cause a reverse taper; therefore in this step, it is particularly preferable to use dry etching.

Next, as shown in FIG. 2(c), in order to close up the side face of the lift-off layer 21 that has been exposed in the separation groove, the separation groove is filled with a filler 23 (the separation groove filling step). The filler 23 is constituted by a material which can be etched at the later-described lift-off step, and for example, Cr can be used as with the lift-off layer 21. Or, a material which can be easily removed by using an organic solvent, or the like, can be used. The filler 23 is formed such that the lift-off layer 21 that has been exposed in the separation groove is at least partially covered.

Next, as shown in FIG. 2(d), an insulator layer 16 is formed (the insulator layer forming step). The insulator layer 16 is formed, on the p-type layer 12c, in a location which is opposed to the n-side electrode 15 as described above. The insulator layer 16 is also formed so as to cover the periphery of the semiconductor layer 12. However, in the separation groove (between semiconductor layers 12), an insulator layer opening 16a is partially formed. In the insulator layer opening 16a, the above-mentioned filler 23 is exposed. Deposition of the insulator layer 16 can be performed by, for example, the CVD method, and thereafter by forming a mask, and making dry etching, patterning can be performed in the geometry shown in FIG. 2(d). The insulator layer 16 is sufficiently thin as compared to the semiconductor layer 12. The pattern on the p-type layer 12c corresponds to the pattern of a later-described n-side electrode 15 (a bonding pad part 15a and an auxiliary electrode 15W.

Next, as shown in FIG. 2(e), a p-side electrode (one electrode) 14 is formed so as to cover the surface of the p-type layer 12c which has been exposed (the first electrode forming step). As the material for the p-side electrode 14, a material which can be ohmically connected to the p-type layer 12c, a simple substance of a metal, such as Ag, Rh, or Ru, or an alloy or a laminated structure containing these can be used. Or, an Au—Ni alloy, a simple substance of Pt or Pd, and an alloy of these can also be used. However, the p-side electrode 14 also functions as a light reflection layer, and from this viewpoint, Ag and its alloy family, which have a reflectivity to visible light as high as 85% or over, or Rh and Ru, which have a high reflectivity in the ultraviolet region, are particularly preferably used in accordance with the application. After sputtering, or the like, of these materials for forming a layer, by performing lithography (mask formation) and etching, the patterning as shown in FIG. 2(e) can be performed. Alternatively, by depositing these materials after making mask formation, and thereafter removing the mask, the same patterning can be performed.

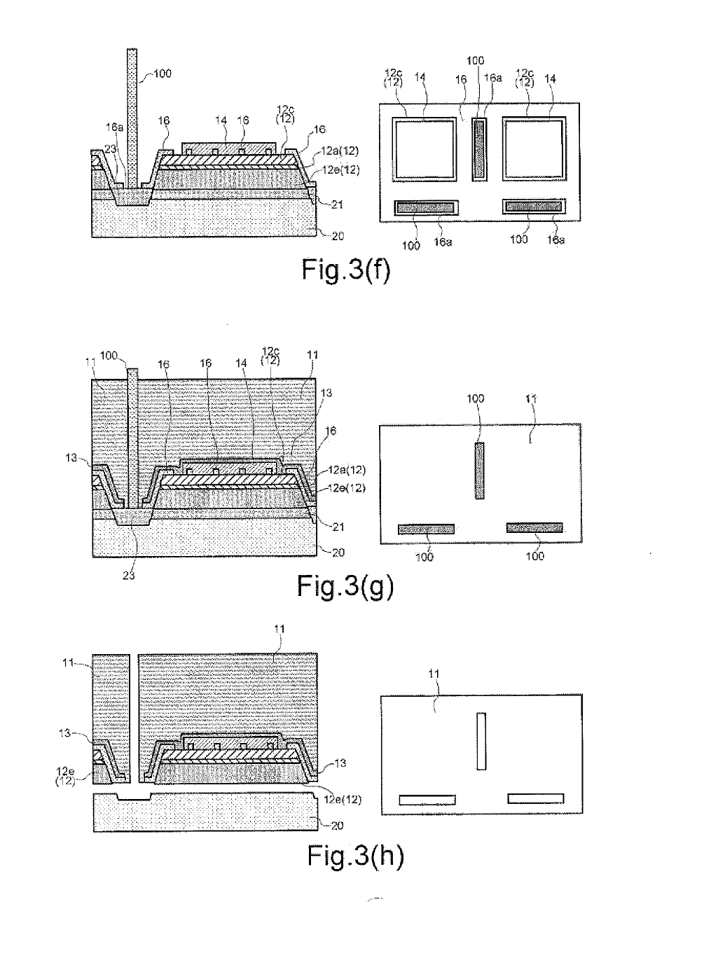

Next, as shown in FIG. 3(f), in the insulator layer opening 16a, a resist layer (mask) 100 composed of a thick photoresist is formed (the opening portion protection step). The thickness of this resist layer 100 must be thicker than that of a supporting portion 11 which is later formed. This step can be performed by lithography. In place of the resist layer 100, a material which functions as a mask in the later-described supporting portion forming step, and can easily be removed before the lift-off step can be used.

Next, as shown in FIG. 3(g), the supporting portion 11 is formed by plating (the supporting portion forming step). In this step, a thin base layer 13 is first formed by vapor deposition, or the like, in the place other than that where the resist layer 100 is formed, and then the supporting portion 11 is formed thick by plating, or the like, with the use of the base layer 13 as a seed layer. The supporting portion 11 is formed such that all the regions other than the resist layer 100, especially the upper portion of the semiconductor layer 12 on the side opposite to the growth substrate 20 and the separation groove, are filled with an electrically conductive material.

The base layer 13 is formed of a material which has a high adherence to the semiconductor layer 12 and the p-side electrode 14, and which can be used as a seed layer in plating. The base layer 13 may have a laminated structure, however, the material at least on the side of the semiconductor layer 12 is preferably a material which can endure the etching at the later-described lift-off step and protection film forming step. Further, if the base layer 13 is to have a high reflectivity as with the p-side electrode 14, it may be provided with a laminated structure having a layer for use as a seed layer, and a reflection layer with a high reflectivity. In this case, as the material for the reflection layer to be provided on the side of the semiconductor layer 12, a platinum family metal, such as Rh or Ru, can be used, and thereon the seed layer can be formed. As the material for the seed layer, it is preferable that, in the case where Ni is to be used as the material for the supporting portion 11 (for Ni plating), Pd be used, while, in the case where Cu is to be used (for Cu plating), Pt/Cu be used. Further, for Ni plating, Ni, Au, Pt, or the like, can be used, and for Cu plating, Ni, Au, Pt, Cu, or the like, can be used. Alternatively, an alloy or a laminated structure based on combination of these metals may be used.

As the material for the supporting portion 11, which is formed by plating, Ni, Cu, Au, or the like, can be used as a material which is different at least from the material for the lift-off layer 21 and the filler 23, and which will not be etched away through the lift-off step. For this plating, either of the dry and wet plating processes can be used, provided that the supporting portion 11 having a sufficient thickness, as depicted in the figure, can be formed. Further, if the wet plating is adopted, either of electroplating and electroless plating can be used.

Next, as shown in FIG. 3(h), after removing the resist layer 100, the lift-off layer 21 and the filler 23 are removed by making a chemical treatment (the lift-off step). By making a selective wet etching treatment, this step can be performed with no ill effect being given to the n-type GaN layer 12e, the p-type layer 12c, the supporting portion 11, and the like. This step is the same as that of the chemical lift-off as disclosed in Japanese Unexamined Patent Application Publication No. 2009-54888, and the like. In the case where the filler 23 is constituted by the same material as that for the lift-off layer 21, the filler 23 and the lift-off layer 21 can be removed at the same time. In the case where the filler 23 will not be etched away by the etchant for the lift-off layer 21, the filler 23 may be first etched away before the lift-off layer 21 being etched away. Since, in the place where there has existed the resist layer 100, no base layer 13 and supporting portion 11 are formed, a thru-hole corresponding to this place is formed in the supporting portion 11. In the lift-off step, with the etchant being supplied through this thru-hole, the filler 23 and the lift-off layer 21 are removed. In the illustrated example, the insulator layer opening 16a is formed between light-emitting element chips which are adjacent to each other in the longitudinal or crosswise direction in the top view, however, the location and shape of the insulator layer opening 16a is optional, provided that the lift-off step is performed. For example, at an intersection of the separation grooves, the insulator layer opening 16a having a cross shape may be formed, and the resist layer 100 may be formed therein. In addition, the insulator layer opening 16a need not be formed in all the gaps between light-emitting element chips, provided that the lift-off step can be performed.

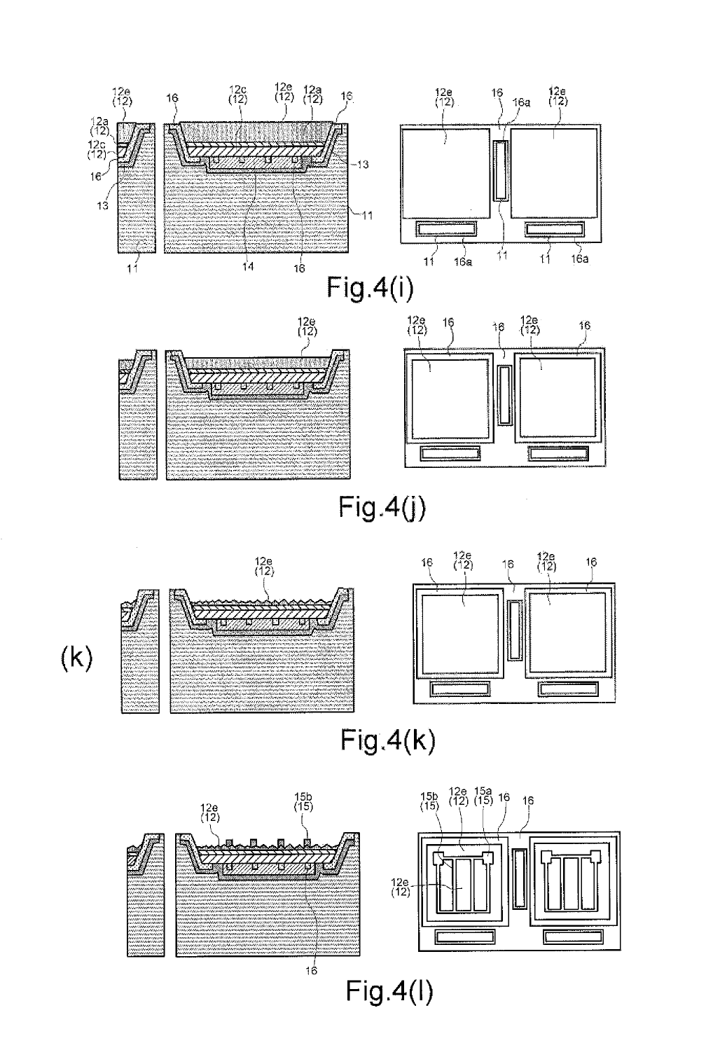

By performing this step, the growth substrate 20 and the semiconductor layer 12 are separated from each other, thereby the bottom face constituted by the n-type layer 12e of the semiconductor layer 12 (the other face) being exposed. This face provides a (000-1) N polar plane, contrarily to the top face of the n-type layer 12e. Hereinafter, since the growth substrate 20 is removed, the supporting portion 11 provides a support substrate for the semiconductor layer 12, and the like. Hereinbelow, as shown in FIG. 4(i), the vertical relationship is inverted to provide the same orientation as that in FIG. 1 for convenience of explanation. In addition, hereinafter, the separated growth substrate 20 will not be required.

In this state, as shown in FIG. 4(j), the exposed n-type layer 12e is uniformly etched away to a predetermined depth (the semiconductor layer etching step). Thereby, the surface of the n-type layer 12e is sunk to under the insulator layer 16 and the supporting portion 11 which are provided at the periphery thereof. This etching can be performed by dry etching using, for example, chlorine (Cl₂) gas and boron trichloride (BCl₃) gas. This etching is preferably not made by anisotropic etching, which is later described, but by isotropic etching. In this case, the surface of the n-type layer 12e after the etching is flat, being unchanged as compared to just after the lift-off step, and remains as a (000-1) N polar plane.

Next, as shown in FIG. 4(k), anisotropic etching is performed on the surface of the n-type layer 12e, thereby irregularities being formed on this surface (the irregularities forming step).

Here, anisotropic wet etching is defined as wet etching with which the etching is selectively progressed for a specific plane orientation. Therefore, in the case where the plane orientation of the macro surface before being subjected to anisotropic etching is different from this specific plane orientation, the surface after the etching is not as flat as that after the semiconductor layer etching step, with a number of irregularities having micro surfaces constituted by a group of planes having such specific plane orientation being formed by the etching. The group of planes having such specific plane orientation can be provided as a group of semipolar {10-1-1} planes, for example.

For such anisotropic wet etching, an alkaline etchant, such as a potassium hydroxide (KOH) solution, a sodium hydroxide (NaOH) solution, or an alkaline solution prepared by mixing of these, can be used. As the solvent, water (H₂O) or glycol can be used. In operation, the OH⁻ ion oxidizes the Group-III atom (Ga or Al) in the GaN or AlGaN layer to thereby cause etching. Especially in the case of GaN, there exist three nitrogen atoms under the Ga atom on the Ga polar plane side, and therefore the OH⁻ ion cannot oxidize the Ga atom. On the other hand, on the nitrogen polar plane side, there exists only one nitrogen atom under the Ga atom, whereby the OH⁻ can oxidize the Ga atom. By making such an anisotropic wet etching treatment using an alkaline etchant under a proper condition, such as heating, the (000-1) N polar plane is selectively etched. On the surface after the etching, there are formed a number of hexagonal pyramid-like convexities, which have a hexagonal bottom face, being derived from the hexagonal crystal. For the above-mentioned reason, such anisotropic etching is caused on the nitrogen polar plane, and the Ga polar plane will not substantially be etched, although the same (000-1) plane is provided for both. On the Ga polar plane, if there is a dislocation, the effect of this etching can be observed as a hexagonal pyramid-like pit. The above point is mentioned in the specification of, for example, International Application No. PCT/JP2010/007611.

Since such irregularities are formed, the area of the surface of the n-type layer 12e is approx. double as large as that of the flat nitrogen polar plane (before the anisotropic etching), regardless of the size of the irregularities. Thereby, even if the dimension of the electrode along the planar direction remains unchanged, the effective area of contact with the n-type electrode 15 is increased, which is effective to reduce the value of contact resistance. The size of the irregularities can be controlled by adjusting the concentration of the etchant, the temperature, and the time, and therefore, it is preferable to provide the size which is suitable not only for the above-mentioned reduction in contact resistance, but also for improvement of the efficiency of light taking-out on the basis of the Snell's law. For example, it is preferable that the convex portion constituted by a hexagonal pyramid have a height of 0.3 to 4.5 μm or so.

Next, as shown in FIG. 4(l), on the surface of the n-type layer 12e in the state in which irregularities have been formed, an n-side electrode 15 is formed (the second electrode forming step). As the material for the n-side electrode 15, such a material as Ti/Ni/Au (a structure in which Ti, Ni, and Au are laminated in this order) can be used. Or, a constitution can be used which has been reported to be effective for this semi-polar plane by the present inventors in PCT Application (International Application No. PCT/JP2010/007611). In addition, as described above, the n-side electrode 15 has a bonding pad part 15a and an auxiliary electrode 15b which is patterned in the shape of a lattice. The deposition method and the patterning method for the n-side electrode 15 are the same as those for the p-side electrode 14. The surface of the n-type layer 12e is constituted by the semi-polar plane, as described above, and therefore, the ohmicity between the n-side electrode 15 and the n-type layer 12e is good, whereby the contact resistance can be reduced. In addition, as described above, the auxiliary electrode 15b serves to enhance the in-face uniformity of light emission.

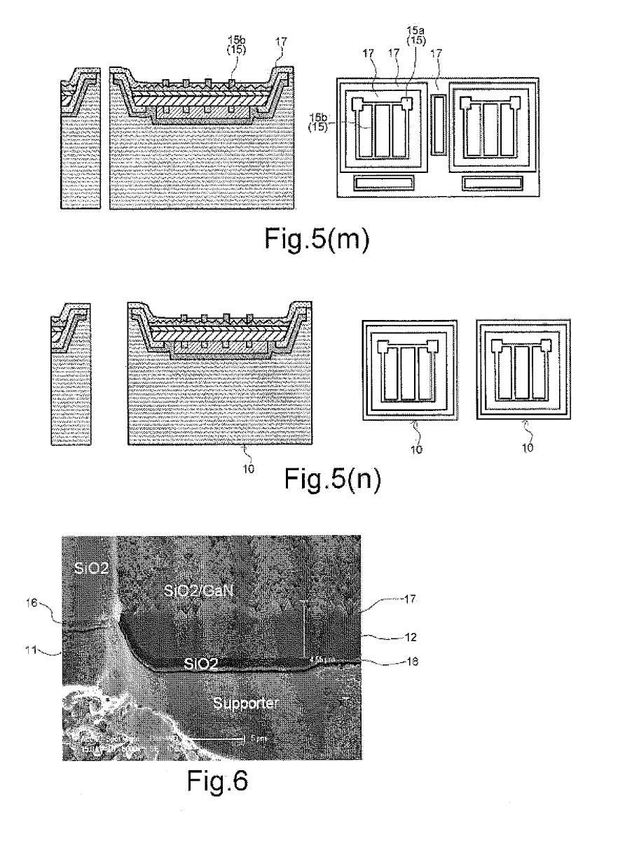

Thereafter, as shown in FIG. 5(m), a protection film 17 is formed over the entire top face except for the place where the n-side electrode 15 is provided (the protection film forming step). As the material for the protection film 17, SiO₂ can be used as with the insulator layer 16. The deposition method therefor is the same as that for the insulator layer 16. For patterning thereof, the protection film 17 may be deposited over the entire top face in FIG. 5(m), and etched away only in the place where the n-side electrode 15 is provided. Or, before the second electrode forming step, the protection film forming step may be performed, and the protection film 17 in the region where the n-side electrode 15 is to be formed may be previously removed before the n-side electrode 15 being formed. In that operation, the maximum height of the n-side electrode 15 in the sectional view (left) in FIG. 5(m) is preferably be lower than the maximum height of the supporting portion 11, and the like, at the periphery thereof by 0.2 μm or over, more preferably by 0.5 μm or over, and still more preferably by 1.0 μm or over. Thereby, at the time of assembling, the collet, jig, and the like, being contacted with the light-emitting face (the n-side electrode 15 and the surface of the n-type layer 12e that is covered with the protection film 17) can be suppressed. The height of such surface can be set as appropriate by adjusting the etching time in the semiconductor layer etching step and the irregularities forming step.

Finally, as shown in FIG. 5(n), the supporting portion 11, and the like, in the separation groove are cut for dividing the wafer into individual light-emitting element chips 10 (the chip separation step). Thus, a number of light-emitting element chips 10 can be obtained from a single wafer.

By the above-described manufacturing method, a plurality of light-emitting element chips 10 having a configuration as shown in FIG. 1 can be manufactured.

Here, especially with GaN, and the like, it is generally difficult to obtain a thick p-type layer 12c, and the mobility of a hole is lower than the mobility of an electron, thereby, the resistivity of the p-type layer 12c is generally higher than the resistivity of the n-type layer 12e. Therefore, in order to reduce the forward resistance of the light-emitting element chip, it is preferable that the area of the p-side electrode 14 be large. On the other hand, the light is obstructed by the n-side electrode 15, it is preferable that the area of the electrode provided on the side of the face where the emitted light is taken out be small. Therefore, like the configuration as shown in FIG. 1, in order to decrease the forward resistance, and increase the luminous efficiency, it is preferable that the n-side electrode 15 which has a small area be formed on the side of the face where the emitted light is taken out.

In addition, by the above-described manufacturing method, the supporting portion outer peripheral portion 11a is made higher than the light-emitting face (the n-side electrode 15 and the surface of the n-type layer 12e that is covered with the protection film 17), thereby the light-emitting face being protected, which is as described above. In addition, as described above, the above-mentioned irregularities and the electrode configuration allow the electrode resistance to be reduced and the light taking-out efficiency to be enhanced. The effect of the protection is especially remarkable for the above-mentioned configuration, in which the electrode is formed on the irregular surface.

Further, the protruded supporting portion outer peripheral portion 11a also functions as a reflecting mirror which reflects the light emitted in the lateral direction toward the upward direction. Therefore, the luminous efficiency of this light-emitting element chip can be particularly enhanced. In this configuration, the taper angle of the supporting portion outer peripheral portion 11a is equal to the taper angle of the side wall of the semiconductor layer 12. This taper angle θ can be set as appropriate by adjusting the dry etching conditions for the semiconductor layer 12 at the separation groove forming step.

The above-mentioned manufacturing method provides a scheme in which the resist layer 100 is used to form a thru-hole in the supporting portion 11, and in which, at the lift-off step, this thru-hole can be utilized to perform removal of the lift-off layer 21, and the like. This thru-hole is formed in the vertical direction with respect to the lift-off layer 21, thereby the etchant is effectively supplied to the lift-off layer 21, whereby the lift-off layer 21 can be etched away at a high efficiency. Therefore, it is particularly preferable that a thru-hole having such a geometry be provided in the supporting portion 11 before the lift-off step. In addition, by forming this thru-hole, the stress between the supporting portion 11 and the semiconductor layer 12 is relaxed, whereby generation of a crack, and the like, in the semiconductor layer 12 can be suppressed. In the above example, the location of the thru-hole is determined by the location of the insulator layer opening 16a and resist layer 100, however, the forming method and the location are optional, provided that the removal of the lift-off layer 21, and the like, can be performed through the thru-hole.

With the manufacturing method illustrated in FIG. 2 to FIG. 5, the n-type layer and the p-type layer constituting the semiconductor layer are sequentially grown on the growth substrate, which is followed by removing the growth substrate. The reason why such a step is taken is that, after forming a laminate structure of the p-type layer and the n-type layer, the p-side electrode and the n-side electrode are to be provided on the different surface sides of the semiconductor layer, respectively. In the case where this semiconductor device is a luminescent diode or laser diode which utilizes this pn junction, such a structure lowers the electrode resistance, and a low forward resistance and a high luminescence efficiency can be achieved. Such a structure is effective for not only the luminescent diode and the laser diode, but also for the whole semiconductor device which operates with a current flowing in a direction perpendicular to the principal plane of this semiconductor layer. This is also true even when another layer is formed between the n-type layer and the p-type layer.

Further, in the above lift-off step, the chemical lift-off method has been used to remove the growth substrate 20. As is well known, as an alternative method for removing the growth substrate 20, the laser lift-off method, which removes the lift-off layer 21 by causing laser light to be absorbed by the lift-off layer 21, can be used. However, in the case where the laser lift-off method is used, the laser light is reflected also by the layers which provide reflection layers at the periphery of the semiconductor layer 12 (the base layer 13 and the supporting portion outer peripheral portion 11a), thereby it being difficult to uniformly remove the lift-off layer in any place in the wafer. Therefore, in the case where such reflection layers are previously formed, it is preferable to use the above-described chemical lift-off method. Especially, in the case where the end portion of the semiconductor layer 12 has a taper angle, uniform lifting-off using the laser lift-off method is more difficult.

Further, in the above example, the case where GaN is used as the Group-III nitride semiconductor has been described, however, for the crystal structure related to the polarity, especially for the structure of the (000-1) N plane and the formation of the semi-polar plane, the same discussion can be applied to other Group-ITT nitride semiconductors, such as AlGaN and AlInGaN. Therefore, it is obvious that the structure and the manufacturing method as described above are also effective for these.

The above embodiment has been explained using a sapphire substrate or AlN template substrate as the growth substrate 20, however, as the growth substrate 20, substrates formed of any other materials, such as SiC and Si substrates, can be used, provided that, through the lift-off layer 21, and the like, good-quality group III nitride semiconductors, such as GaN, AlN, AlGaN, and BAlInGaN (for use as the n-type layer 11a, the luminescent layer 11b, and the p-type layer 11c) can be grown.

In the above example, the semiconductor layer 12 has been explained assuming that it is constituted by the n-type layer 12e, the luminescent layer 12a, and the p-type layer 12c each being formed of a GaN based material. However, even in other cases, it is obvious that the same effect is provided. For example, it is also obvious that a diode which utilizes a simple pn junction, or various semiconductor devices can be manufactured in the same manner. In the above example, the n-type layer and the p-type layer have been sequentially formed on the growth substrate, however, even if the order of the n-type layer and the p-type layer is inverted, the description is also true. In addition, the n-type layer and the p-type layer may not be formed of GaN, but of any other group III nitride semiconductor, for example, AlₐIn_{b}Ga_{1-a-b}N (0≦a≦1, 0≦b≦1, and a+b≦1).

### Example

Hereinbelow, the result of actually manufacturing a light-emitting element chip having the above-mentioned configuration will be explained.

First, after forming the lift-off layer 21 (Cr and CrN as a result of nitriding the Cr, with a thickness of 18 nm) on the sapphire substrate (the growth substrate 20), the semiconductor layer 12 composed of the n-type layer 12e (n-type GaN, with a thickness of 7 μm), the InGaN MQW luminescent layer 12a (with a thickness of 0.1 μm), the p-type layer 12c (p-type GaN, with a thickness of 0.2 μm) was formed (the epitaxial growth step). Then, by the dry etching method, a part of the semiconductor layer 12 was removed to form separation grooves for separating the individual element regions of the p-type layer 12c, each being composed of a square of 1000 μm per side (the separation groove forming step). Here, the taper angle A of the end portion of the semiconductor layer 12 was specified to be 40° with the pitch between elements being specified to be 1250 μm. The formation of the separation grooves was performed by etching away the sapphire substrate by 0.2 μm, and confirming that the sapphire substrate was exposed. On the sapphire substrate surface which was exposed, a Cr layer which is thick enough to be able to cover the side face of the exposed lift-off layer 21 and a part of the n-type layer 12e (i.e., with a thickness of 400 nm) was formed by the lift-off method using a resist pattern (the separation groove filling step).

Over the entire surface in this configuration, the insulator layer 16 (SiO₂, with a thickness of 350 nm) was formed, and a part of the insulator layer 16 on the Cr layer (the insulator layer opening 16a) and a part of the insulator layer 16 on the p-type layer 12c in the element region were removed with buffered hydrofluoric acid (BHF) (the insulator layer forming step). The insulator layer opening 16a was specified to be a portion having a width of 70 μm and a length of 900 μm in the central area of the separation groove which is located along each of the four sides of the element region. The insulator layer 16 on the p-type layer 12c was removed, except for that in the location opposed to the location of the auxiliary electrode 15b in the n-side electrode 15, thus 80% of the area of the p-type layer 12c having been exposed. Thereafter, on the exposed p-type layer 12c, the p-side electrode 14 (Ag, with a thickness of 0.2 μm) was formed (the first electrode forming step). At this time, a gap of 10 μm was provided between the p-side electrode 14 and the insulator layer 16 which is located at the periphery of the p-type layer 12c.

Further, the exposed filler 23 (the Cr layer) in the insulator layer opening 16a was covered with a photoresist, and a base layer 13 (Ni (100 nm)/Au (100 nm)/Cu (0.2 μm) was formed on the p-side electrode 14 and the insulator layer 16, and on the p-type layer 12c in the gap between these. Thereafter, by removing the photoresist, the base layer 13 in FIG. 3(g) was obtained. The base layer 13 which is given in the above-mentioned gap also plays a role of preventing the diffusion of the p-side electrode 14 formed of Ag. In the case where a metal other than Ag that is difficult to be diffused is used, this gap is not always needed.

Thereafter, on a part of the exposed Cr layer, a thick-film resist (the resist layer 100) having a width of 70 μm, a length of 900 μm, and a thickness of 100 μm was formed (the opening portion protection step).

Thereafter, using a copper sulfate based electrolyte and the base layer 13 as the seed, the supporting portion 11 formed of Cu having a thickness of 150 μm from the connection layer surface of the semiconductor layer was formed by electroplating (the supporting portion forming step). The supporting portion 11 is integrally formed over the entire area of the sapphire substrate.

Thereafter, using acetone, the thick-film resist was dissolved. Thereby, a hole or groove which penetrates from the surface of the supporting portion 11 to the filler 23 (the Cr layer) on the sapphire substrate was formed. Thereafter, by immersing the wafer in a Cr etchant with which Cr as well as CrN are selectively etched away, and through this thru-hole or groove, supplying the etchant to the Cr layer and the CrN layer 21 as the lift-off layer to dissolve the lift-off layer 21, the sapphire substrate 20 was peeled off (the lift-off step).

Thereafter, the n-type layer 12e of the lift-off surface was uniformly dry etched (the semiconductor layer etching step). By this etching, the n-type layer 12e was etched away from a thickness of 7 μm to a thickness of 5 μm. Further, by immersing the wafer in a KOH aqueous solution (6 mol/L) at 60° C. for 30 minutes, irregularities having a hexagonal pyramid-like shape with various sizes, the height from bottom to apex of the irregularities ranging from 0.4 to 1.5 μm, were formed on the surface (the irregularities forming step). In this case, the thickness of the n-type layer 12e from the uppermost point was specified to be 3.5 μm. Thereafter, the protection film 17 (SiO₂) was deposited by 0.2 μm (the protection film forming step), and the protection film 17 in the place where the n-side electrode 15 is to be formed was removed by etching with BHF to expose the surface of the n-type layer 12e. On the surface of this n-type layer 12e having a surface in the hexagonal pyramid-like shape, the n-side electrode 15 (Ti/Ni/Au, with a thickness of 1.5 μm) having the auxiliary electrode 15b and the bonding pad part 15a corresponding to the pattern of the above-mentioned insulator layer 16 was formed (the second electrode forming step). FIG. 6 is an SEM photograph showing the section in the vicinity of the outer peripheral portion of the light-emitting element chip after having been completed when viewed from diagonally above.

Finally, the difference in level between the surface of the n-type layer 12e (the apex of the hexagonal pyramid) and the surface of the top portion 11b of the supporting portion 11 made of Cu and having a concave geometry (exactly, the protection film surface) was approximately 2 μm (1.8 μm or over).

Using a flat collet, the assembly test was conducted on ten thousands pieces of the light-emitting element chip 10 in the present Example. The contact surface between the collet and the light-emitting element chip 10 is the supporting portion outer peripheral portion 11a, and since the collet will not be contacted with the surface of the n-side electrode 15 and the n-type layer 12e, no flaws and dents were generated on the surface of the upper electrode 15 and the n-type layer 12e.

### Comparative Example

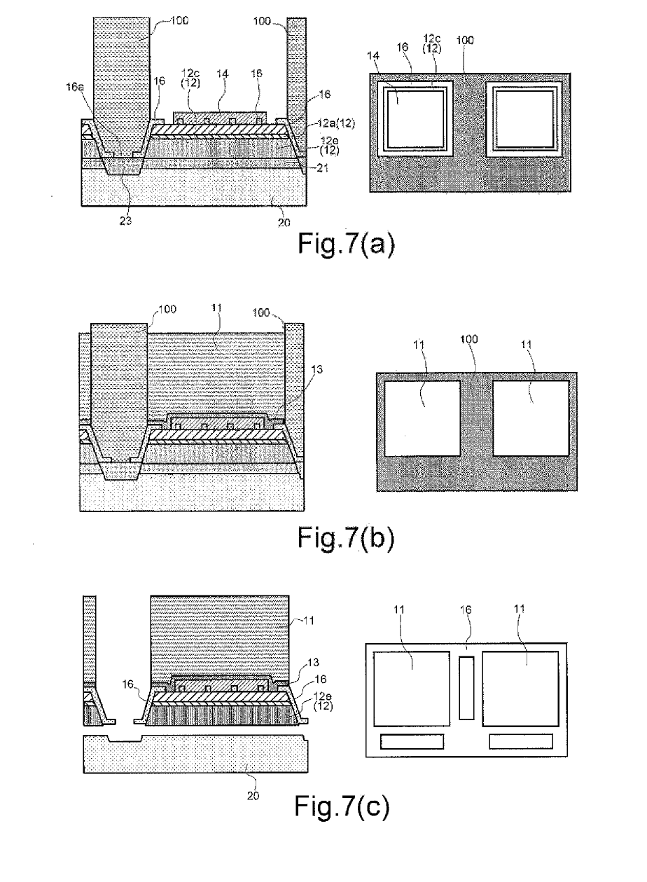

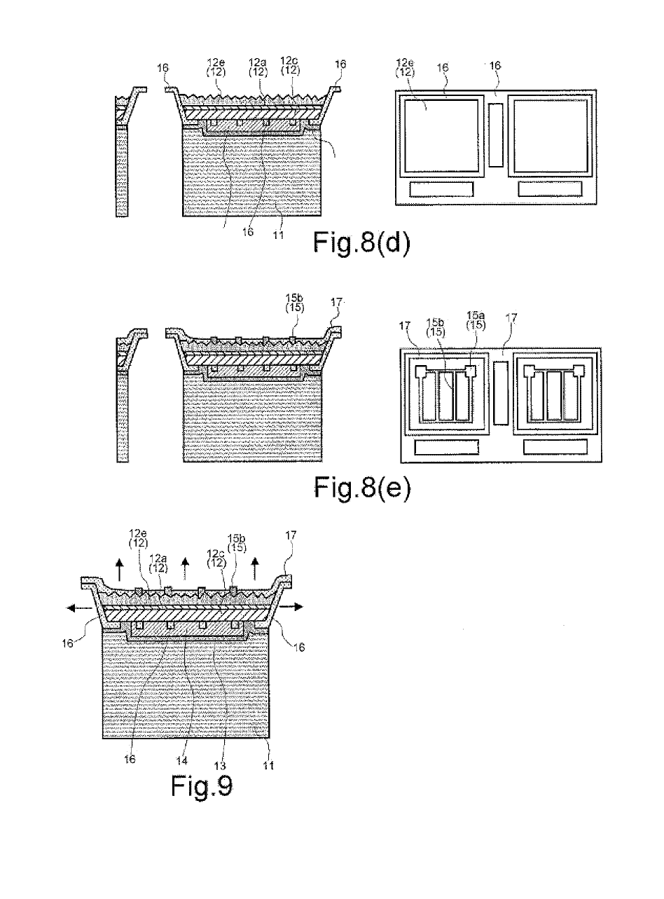

Herein, as Comparative Example, a light-emitting element chip with a structure having no supporting portion outer peripheral portion 11a as that in Example was manufactured. This manufacture was performed by filling up all the separation grooves between semiconductor layers in the opening portion protection step with photoresist, and performing the other steps in the same manner. FIG. 7 gives drawings illustrating the schemes of the opening portion protection step (a), the supporting portion forming step (b), and the lift-off step (c) in this manufacturing method in the same manner as that for Example. In addition, FIG. 8 illustrates the schemes of the irregularities forming step (d) and the protection film forming step (e) in the same manner as that for Example. The steps before the opening portion protection step are the same as in Example, and the geometry in the step which is a step subsequent to the lift-off step, but not illustrated in FIG. 8 is the geometry according to that shown in FIG. 8(d) and FIG. 8(e).

In other words, in Comparative Example, there is provided the light-emitting element chip having a sectional structure shown in FIG. 9 in which the supporting portion 11 (the supporting portion outer peripheral portion 11a) is not formed at the periphery of the semiconductor layer 12. With the light-emitting element chip of this structure, except that, in the outer peripheral portion thereof, the supporting portion 11 which is protruded upward (i.e., the supporting portion outer peripheral portion 11a) is not formed, the structure (the semiconductor layer 12, and the like) is the same as that for Example, and the conditions for the respective manufacturing steps (for example, the dry etching conditions, and the like, for the semiconductor layer 12 in the separation groove forming step) are the same. In FIG. 9, the insulator layer 16 and the protection film 17 are drawn for convenience such that they are protruded to above the semiconductor layer 12, however, actually, such protruded portion is in the thin-film state, and there exists no structure which mechanically supports that portion. Therefore, the state of the insulator layer 16 and the protection film 17 at the periphery of the light-emitting face that is shown in FIG. 9 will not be actually maintained at the time of manufacturing or assembly. In other words, such protruded insulator layer 16 and protection film 17 will not have a protection function for the light-emitting face like that of the above-mentioned supporting portion outer peripheral portion 11a.

Using a flat collet, the assembly test was conducted on ten thousand pieces of the light-emitting element chip 10 in this Comparative Example. As a result of the test, a flaw or chipping was observed in 151 pieces of the ten thousand pieces. In addition, a crack caused in the semiconductor layer was observed in 58 pieces of the ten thousand pieces. From the above-mentioned results, it has been verified that, in accordance with the present invention, no flaws or dents are produced in the n side electrode 15 (particularly in the auxiliary electrode 15b), and no impact is applied to the semiconductor layer at the time of assembly, whereby the assembly can be performed safely.

(Output Characteristics Example)

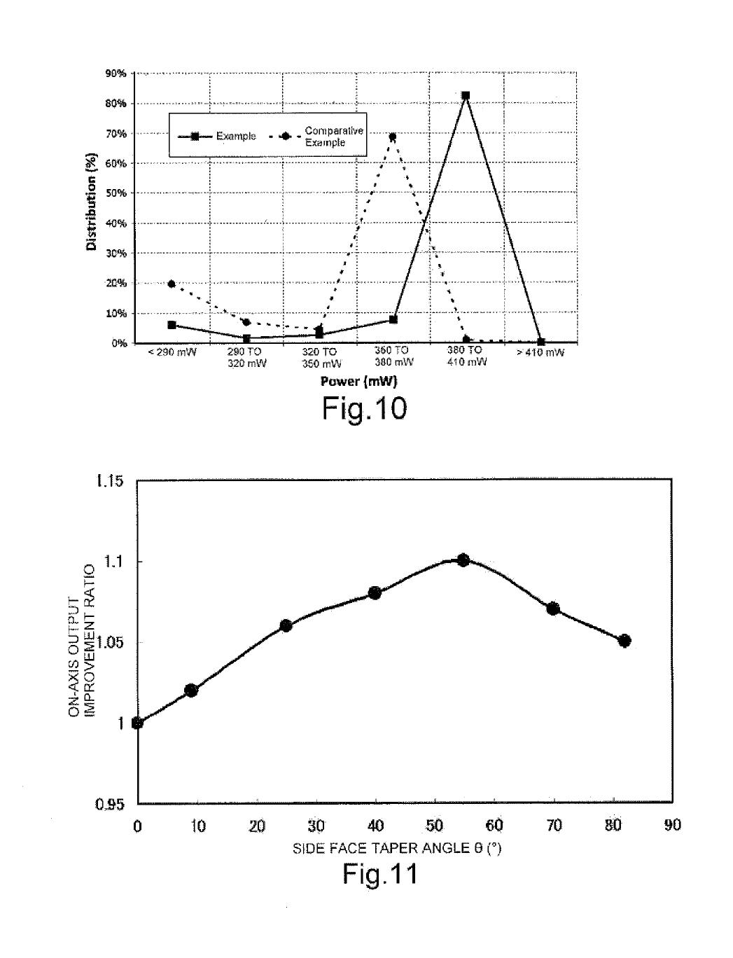

One thousand pieces of the light-emitting element in which the light-emitting element chip according to Example is assembled were caused to emit light by using a constant current power supply to feed a current of 350 mA. Around the light-emitting element chip, there is formed no structure, such as a reflection cup, or a plastic lens, which can have an effect on the luminous efficiency, except for the light-emitting element chip itself. FIG. 10 is a histogram of the results of actual measurement of the emission intensity of the on-axis light emission output at room temperature with the elements in Example and Comparative Example. With the light-emitting element in Example, the light-emitting elements of 80% or over exhibited a light emission output of 380 mW to 410 mW. Contrarily to this, with the light-emitting element in Comparative Example, the light-emitting elements of 70% exhibited a light emission output of 350 mW to 380 mW. This results reveal that, with the light-emitting element chip in Comparative Example in which the conventional flat supporting portion is used, as shown in FIG. 9, the light emitted from the luminescent layer in the lateral direction is leaked in the lateral direction as it is, thereby the light could not have been taken out upward with a sufficient effectiveness. On the other hand, with the light-emitting element chip in Example, the light which has reached the side face from the luminescent layer 12a is reflected at the supporting portion outer peripheral portion 11a, whereby the light can be effectively taken out upward. In other words, it has been found that the light-emitting element chip in Example improves the on-axis light emission output by itself.

### (Effect of Taper Angle)

As described above, the taper angle θ for the semiconductor layer or the supporting portion outer peripheral portion can be controlled by adjusting the dry etching conditions in the separation groove forming step. In addition, this taper angle θ can have an effect on the efficiency of light taking-out. FIG. 11 indicates the result of actual determination of the relationship between the light emission output in the vertical direction (the on-axis output improvement ratio, which is assumed to be 1.0 for θ=0°) and θ in FIG. 1(b). From this result, it can be the that, by increasing the value of θ from 0, the light emission output is increased, and reaches a maximum value at θ=55°. In the case where the value of θ is brought to near 90°, the area of the entire light-emitting chip will be increased for a given area of the light-emitting face, which is not preferable.

### (Reduction in Amount of Phosphor)

The light-emitting element chip or the light-emitting element having the above-described configuration emits monochromatic light the color of which is determined by the material composition of the semiconductor layer 12. Contrarily to this, by forming a phosphor layer on the light-emitting face of the light-emitting element chip, light as a result of the light emitted by this phosphor layer being mixed with the light emitted by the semiconductor layer can be obtained. Here is a description about the case where, in order to obtain a pseudo white color, YAG emitting a yellow color is used as this phosphor on the light-emitting element emitting a blue color.

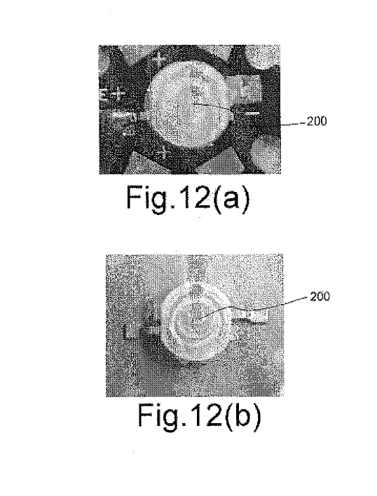

This phosphor layer is formed on the light-emitting face by baking it after being applied, however, it is required that the entire place of the semiconductor layer from which the emitted-light is taken out be covered with this phosphor layer. FIG. 12 gives photographs of the top view for the light-emitting element chip in Example, (a), and the light-emitting element chip in Comparative Example, (b), after this phosphor layer 200 having been formed. In Example, (a), the thickness of the phosphor layer 200 at the top face is 70 μm or so. In addition, since light will not be emitted from the side face, there is no need for forming the phosphor layer 200 on the side of the side face. In addition, as can be seen from FIG. 1, in Example, the outer peripheral portion of the light-emitting face is at a higher level, thereby, upon the liquid phosphor material being applied, the phosphor material flowing outward was suppressed by the surface tension.

On the other hand, in Comparative Example, as stated in, for example, Japanese Unexamined Patent Application Publication No. 2008-135539, it becomes necessary to form the phosphor layer 200 also at the side face. Therefore, the quantity of the phosphor material used was increased as compared to that in Example, being approximately three times the quantity required for that in Example. Further, in order to obtain uniform light emission, the thickness of the phosphor layer 200 is required to be uniform in all the places. However, in the case where the phosphor layer is to be formed both at the top face and the side face, it is difficult to provide a uniform thickness in all the places.

On the other hand, in Example, the light-emitting face has a structure in which the periphery thereof is raised as a bank, and only in the inside of this periphery, the phosphor layer 200 is needed to be formed, thereby it is easy to make the thickness of the phosphor layer 200 uniform within this bank like portion. Thereby, with the light-emitting element chip in Example, it is possible to suppress the increase in quantity of use of the expensive phosphor, and, in addition, to facilitate the control of the emitted-light color.

The configuration, geometry, size, and positional relationship which have been explained in the above embodiment are only those outlined to such an extent that the present invention can be understood and embodied, and in addition, the numerical values, the compositions of the respective components, and the like, are given only as exemplifications. Therefore, the present invention is not limited to the embodiment which has been explained, and can be modified to various embodiments within the scope of the technical concept as given in the claims.

### INDUSTRIAL APPLICABILITY

The light-emitting element chip and the manufacturing method therefor in accordance with the present invention are applicable to LED optical system elements and methods for manufacturing the same.

### DESCRIPTION OF SYMBOLS

Reference symbol 10 denotes a light-emitting element chip; 11 a supporting portion; 11a a supporting portion outer peripheral portion; 11b a top portion; 12 a semiconductor layer; 12a a luminescent layer; 12b a one face; 12c a p-type GaN layer (p-type semiconductor layer: p-type layer); 12d the other face; 12e an n-type GaN layer (n-type semiconductor layer: n-type layer); 13 a base layer; 14 a p-side electrode (one electrode); 15 an n-side electrode (the other electrode); 15a a bonding pad part (n-side electrode); 15b an auxiliary electrode (n-side electrode); 16 an insulator layer; 16a an insulator layer opening; 17 a protection film; 20 a growth substrate; 21 a lift-off layer; 23 a filler; 100 a resist layer (mask); and 200 a phosphor layer.

1. A light-emitting element chip, comprising a configuration in which a semiconductor layer having a luminescent layer is formed on a conductive supporting portion, said supporting portion being connected to one electrode connected to one face of said semiconductor layer,
irregularities being formed on the other face of said semiconductor layer, and the other electrode being formed on said other face,
said supporting portion having an outer peripheral portion surrounding the periphery of the other face of said semiconductor layer, with the outer peripheral portion being protruded to above the other face of said semiconductor layer and said other electrode.

2. The light-emitting element chip according to claim 1, wherein the top portion of said outer peripheral portion is located higher than the surface of said other electrode by 0.2 μm or over.

3. The light-emitting element chip according to claim 1, wherein the side face of said semiconductor layer is tapered, being adjacent to the outer peripheral portion of said supporting portion with at least an insulator layer being sandwiched therebetween.

4. The light-emitting element chip according to claim 1, wherein said supporting portion is integrally formed by a dry or wet deposition method, being made of a metal or an alloy.

5. The light-emitting element chip according to claim 1, wherein said semiconductor layer is formed of a group III nitride semiconductor, micro surfaces constituting the irregularities on said other face providing a semi-polar plane composed of a group of {10-1-1} planes.

6. A light-emitting element chip manufacturing method for manufacturing a plurality of light-emitting element chips using a single growth substrate, comprising:
the epitaxial growth step of sequentially forming a lift-off layer and a semiconductor layer having a luminescent layer on said lift-off layer on said growth substrate;
the separation groove forming step of forming, between places corresponding to adjacent light-emitting element chips, a separation groove in which said growth substrate is exposed by removing said semiconductor layer and said lift-off layer;
the insulator layer forming step of forming an insulator layer which at least surrounds the side face of said semiconductor layer that faces said separation groove;
the first electrode forming step of forming one electrode on one face of said semiconductor layer that is the surface thereof on the side opposite to said growth substrate;
the supporting portion forming step of forming a supporting portion for supporting said semiconductor layer on the face of said semiconductor layer on the side opposite to said growth substrate, and in said separation groove;
the lift-off step of separating said semiconductor layer and said growth substrate from each other by removing said lift-off layer by a wet treatment;
the semiconductor layer etching step of etching away the other face of said semiconductor layer that has been exposed by said lift-off step, thereby said supporting portion surrounding the periphery of the other face being protruded to above said other face;
the irregularities forming step of performing a treatment for forming irregularities on said other face; and
the second electrode forming step of forming the other electrode on said other face.

7. The light-emitting element chip manufacturing method according to claim 6, wherein, in said separation groove forming step, the side face of said semiconductor adjacent to said separation groove is tapered.

8. The light-emitting element chip manufacturing method according to claim 6, wherein, in said irregularities forming step, said other face is etched away using an alkaline solution.

9. The light-emitting element chip manufacturing method according to claim 6, wherein, in said supporting portion forming step, said supporting portion is formed such that there exists a thru-hole in said supporting portion; and
in said lift-off step, an etchant for etching away said lift-off layer is supplied to said lift-off layer through said thru-hole.
